(19) United States
(12) Patent Application Publication
(10) Pub. No.: US 2026/0177627 A1
(43) Pub. Date: Jun. 25, 2026

(54) ELECTRIC POWER AMOUNT ESTIMATION APPARATUS, ELECTRIC POWER AMOUNT ESTIMATION METHOD, AND PROGRAM

(71) Applicant: NTT, Inc., Tokyo (JP)

(72) Inventors: Miho IWAMOTO, Tokyo (JP); Toru TANAKA, Tokyo (JP); Masaki KOZAI, Tokyo (JP); Hiroya MINAMI, Tokyo (JP)

(21) Appl. No.: 19/125,840

(22) PCT Filed: Dec. 13, 2022
(86) PCT No.: PCT/JP2022/045933

§ 371 Date: Apr. 30, 2025

(51) Int. Cl. G01R 31/382; G01R 31/367; G01R 31/374; G01R 31/389; G01R 31/392

(52) U.S. Cl. CPC G01R 31/382; G01R 31/367; G01R 31/374; G01R 31/389; G01R 31/392

(57) ABSTRACT

An electric power amount estimation apparatus, that estimates a dischargeable amount that is dischargeable from one or more batteries, includes an acquisition unit which acquires a residual capacity prediction value and a prediction error of each of the one or more batteries; and an estimation unit which determines an adjustment prediction value that is a value less than a residual capacity prediction value, on at least one battery among the one or more batteries, based on a prediction error, and estimates the dischargeable amount, using the adjustment prediction value.

### TECHNICAL FIELD

The present invention relates to a technique for predicting a residual battery capacity of an electric vehicle (EV).

### BACKGROUND ART

Non-Patent Literature 1 discloses a technique for preventing battery exhaustion (power shortage) of an EV on an expressway and recommending a charging place to a driver. In the technique, charging information of an EV, traffic information such as traffic congestion, weather information, and the like are accumulated as past history data, and based on this, the power consumption is estimated from the traveling conditions of the EV.

### CITATION LIST

### Non-Patent Literature

Non-Patent Literature 1: Toshiba “System to Support EV Drivers Travelling on Expressways and Its Technology Using AI to Predict Power Consumption of EVs,” EV charging navigation system https://www.global.toshiba/content/dam/toshiba/migrat ion/corp/techReviewAssets/tech/review/2017/03/72_03pd f/a04.pdf

### SUMMARY OF INVENTION

### Technical Problem

The utilization of EV batteries to adjust power supply and demand is being considered. In the supply and demand adjustment, power remaining in the EV battery can be supplied to a load of a building, or power remaining in PV power generation can be charged to the EV battery.

In order to plan the supply and demand adjustment, it is necessary to predict the residual battery capacity in the future. However, there is a possibility that an unallowable error is included in the prediction of the residual battery capacity. When a prediction value having an unallowable error is used, it is difficult to appropriately estimate the dischargeable amount from the battery used for the supply and demand adjustment and the chargeable amount to the battery. For example, there may be a case where the battery cannot be discharged to the estimated dischargeable amount or the battery cannot be charged to the estimated chargeable amount.

This problem is not limited to the case where the battery is used for the supply and demand adjustment, but may occur in any case where the dischargeable amount of the battery or the chargeable amount of the battery is used.

The present invention was made in view of the above points, and an object thereof is to provide a technique for appropriately estimating the amount of discharge or charge that can be performed on a battery.

### Solution to Problem

According to the disclosed technique, there is provided an electric power amount estimation apparatus that estimates a dischargeable amount that is dischargeable from one or more batteries, the electric power amount estimation apparatus including: an acquisition unit that acquires a residual capacity prediction value and a prediction error of each of the one or more batteries; and an estimation unit that determines an adjustment prediction value that is a value less than a residual capacity prediction value, on at least one battery among the one or more batteries, based on the prediction error, and estimates the dischargeable amount using the adjustment prediction value.

### Advantageous Effects of Invention

According to the disclosed technique, it is possible to appropriately estimate the dischargeable amount or the chargeable amount in the battery.

### BRIEF DESCRIPTION OF DRAWINGS

FIG. 1 is a diagram illustrating an overall configuration of a system.

FIG. 2 is a diagram illustrating a configuration of a charge/discharge surplus power calculation device 100.

FIG. 3 is a flowchart explaining the operation of the charge/discharge surplus power calculation device 100.

FIG. 4 is a diagram explaining adjustment of a prediction value.

FIG. 5 is a diagram illustrating a configuration of a required electric power amount prediction unit 110.

FIG. 6 is a flowchart explaining the operation of the required electric power amount prediction unit 110.

FIG. 7 is a diagram illustrating a configuration of an EV electric power amount prediction unit 120.

FIG. 8 is a flowchart explaining the operation of the EV electric power amount prediction unit 120.

FIG. 9 is a diagram illustrating an example of a relationship between speed and errors (RMSE) of three types of prediction models.

FIG. 10 is a diagram illustrating a configuration of an electric power amount estimation apparatus 150.

FIG. 11 is a diagram illustrating an example of the hardware configuration of the device.

### DESCRIPTION OF EMBODIMENTS

Hereinafter, an embodiment of the present invention (the present embodiment) will be described with reference to the drawings. The embodiment to be described below is only one example, and an embodiment to which the present invention is applied is not limited to the following embodiment.

In the following description, an electric vehicle is assumed as a vehicle equipped with a battery, but a target of the present invention is not limited to an electric vehicle. For example, the vehicle may be a motorcycle, agricultural machinery, a ship, a train, a hybrid vehicle, or the like. Furthermore, these may be collectively referred to as an EV or an electric vehicle. Hereinafter, “EV” is mainly used.

In the technique according to the present invention, the battery may be mounted on an object other than a vehicle. In addition, although an example in which the technique according to the present invention is applied to the preparation of a charge and discharge plan in the supply and demand adjustment is described below, this technique according to the present invention is not limited to the preparation of the charge and discharge plan, and is applicable to various fields.

### Problems of Technique According to Embodiment

As mentioned above, there is a movement to use EV batteries to adjust electricity supply and demand. In order to utilize the battery of the EV for supply and demand adjustment, it is necessary to find a charge/discharge surplus power (SOC: state of charge) at a future time from several days to several hours before the target time of supply and demand adjustment, and to make a charge/discharge plan.

In order to find (estimate) the remaining capacity (dischargeable amount/chargeable amount) of the battery at the future time, it is necessary to predict the amount of power consumption (or remaining battery amount) of the EV until that time.

However, in the related art for predicting the power consumption of the EV (e.g., the technique disclosed in Non-Patent Literature 1), a large prediction error that cannot be allowed may occur. Therefore, when the prediction value obtained by the related art is used for preparing the charge/discharge plan as it is, there is a possibility of leading to a deviation from the charge/discharge plan depending on the magnitude of the error, which hinders the charge/discharge.

In order to utilize the battery of the EV to the maximum extent without affecting the running of the EV, it is necessary to prepare a highly reliable charge/discharge plan in consideration of the running schedule of each EV. Hereinafter, the system configuration and operation for solving the above problems will be described.

### (System Configuration)

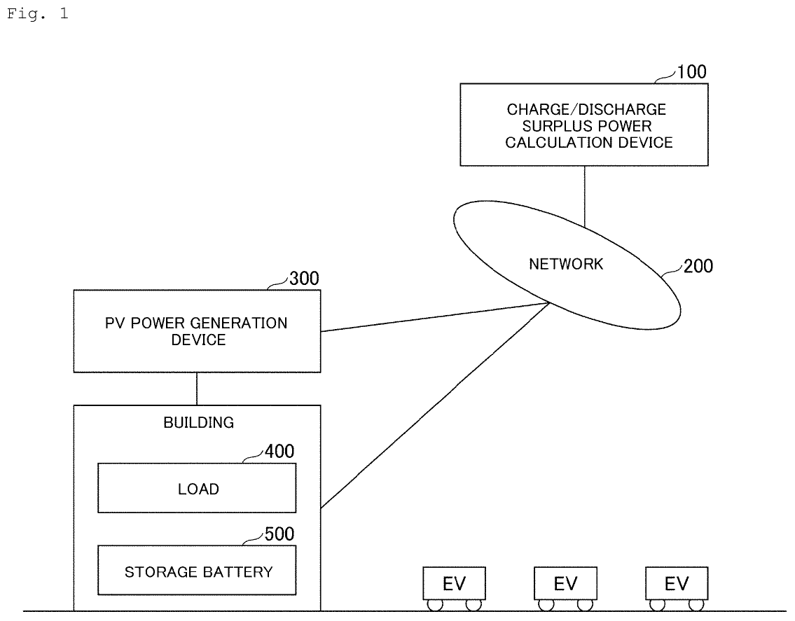

FIG. 1 illustrates an example of a system configuration assumed in the present embodiment. In the system illustrated in FIG. 1, there is a building, such as a company building. The building includes a load 400, which includes various devices consuming electric power, and a storage battery 500. A PV power generation device 300 (photovoltaic power generation device) is also provided. The PV power generation device 300 is an example of a renewable energy power generation device. Also, there are a plurality of EVs used for business in the company, for example.

The power used by the load 300 in the building is supplied by PV power generation (or PV power generation and commercial power supply). When the power of the load 300 is insufficient in PV power generation, the power remaining in the battery of the EV is supplied to the load 300. Further, the power of the storage battery 500 may be supplied to the load 300.

When the PV power generation amount is larger than the power required by the load 300, the power of the PV power generation is charged in the battery of the EV.

In the present embodiment, it is assumed that the supply and demand adjustment is performed in a planned manner. A charge/discharge surplus power calculation device 100 is connected via a network 200. The charge/discharge surplus power calculation device 100 can create a charge/discharge plan for supply and demand adjustment.

In the present embodiment, it is assumed that each EV is used for business, and therefore, the travel schedule is assumed to be known in advance. It is also possible to collect travel history data (the start/return time, the travel distance, the average speed, the travel route, and the like) after the EV travel.

### Example of Device Configuration

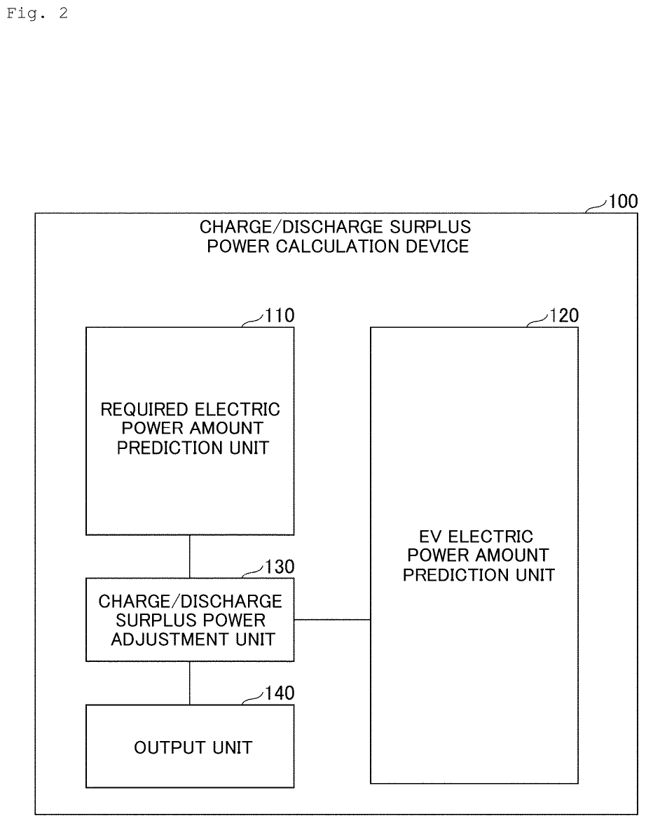

FIG. 2 illustrates a configuration example of the charge/discharge surplus power calculation device 100. As illustrated in FIG. 1, the charge/discharge surplus power calculation device 100 includes a required electric power amount prediction unit 110, an EV electric power amount prediction unit 120, a charge/discharge surplus power adjustment unit 130, and an output unit 140.

The required electric power amount prediction unit 110 performs demand amount prediction and power generation amount prediction using a model constructed from actual values of a power demand amount of a building and a power generation amount of PV power generation. An existing method can be used for these predictions. The required electric power amount prediction unit 110 further performs priority determination (charging priority or discharging priority) of charge and discharge at each time depending on a purpose (for example, load leveling, such as peak cut, and surplus absorption of renewable energy) from a difference (=net demand) between the predicted power generation amount and demand amount, and calculates necessary a discharge electric power amount or charge electric power amount.

The EV electric power amount prediction unit 120 performs SOC prediction (residual battery capacity prediction) of the EV, using a prediction model with a use schedule of the EV as an input, and calculates a prediction value and a prediction error.

As will be described later, it is possible to construct a prediction model suitable for each average speed (in which prediction accuracy is secured).

The charge/discharge surplus power adjustment unit 130 determines an EV (an object of adjustment) including an unallowable error based on a predetermined allowable error (threshold), and adjusts the surplus power (residual battery capacity). When the prediction error is allowed, the adjustment is not required.

The charge/discharge surplus power adjustment unit 130 allocates required discharge power/charge power in the following order (1) to (3), and reflects it on a charge/discharge plan.
(1) A residual battery capacity of an EV having a highly accurate prediction value (including absence of any scheduled trip)
(2) A residual battery capacity of an EV adjusted to the safety side by taking into account a large deviation since the prediction error is great
(3) Stationary storage battery
   The output unit 140 outputs a result of the allocation performed by the charge/discharge surplus power adjustment unit 130 as a charge/discharge plan.

### Operation of Device

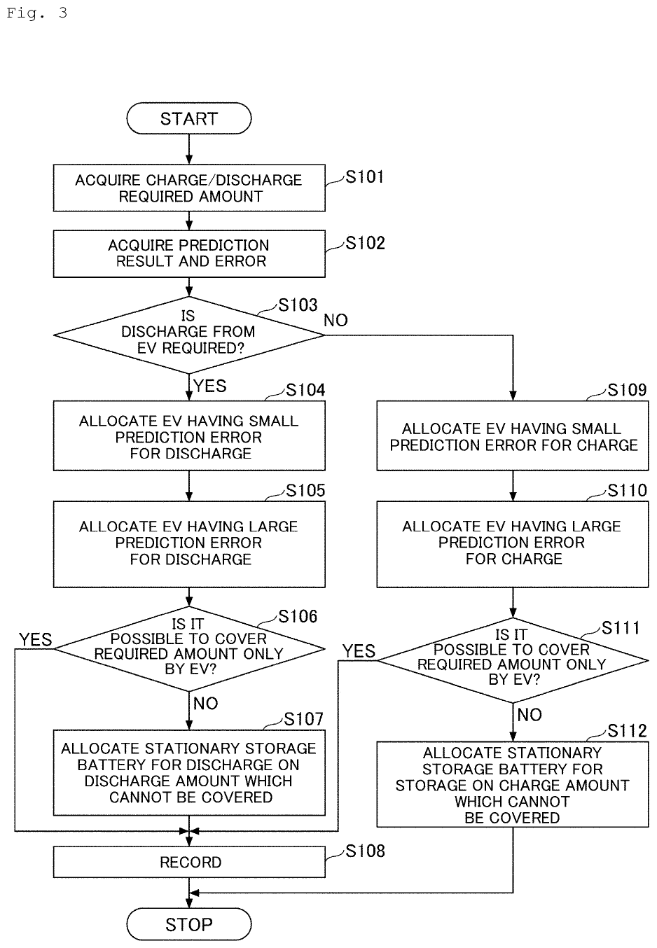

Next, the operation related to the charge/discharge surplus power adjustment in the charge/discharge surplus power calculation device 100 will be described in detail referring to the flowchart of FIG. 3.

### <S101>

In S101, the charge/discharge surplus power adjustment unit 130 acquires a required discharge amount (electric power amount of discharge) or a required charge amount (electric power amount of charge) for each future time determined (predicted) by the required electric power amount prediction unit 110.

More specifically, in the required electric power amount prediction unit 110, in a case where “demand amount>power generation amount”, it is determined that discharge by the EV is necessary to cover insufficient power in the discharge from the EV, and “demand amount−power generation amount” is obtained as a required discharge amount.

When “demand amount<power generation amount” in the required electric power amount prediction unit 110, it is determined that the surplus power generation amount is required to be charged to the EV, and “power generation amount−demand amount” is obtained as the required charge amount.

In S101, the charge/discharge surplus power adjustment unit 130 acquires a required discharge amount or a required charge amount for each future time obtained in the above manner from the required electric power amount prediction unit 110.

### <S102>

In S102, the charge/discharge surplus power adjustment unit 130 acquires a future SOC prediction result (a prediction value of a residual battery capacity) and a prediction error for each EV determined by the EV electric power amount prediction unit 120.

For example, when EV1, EV2, and EV3 exist, the charge/discharge surplus power adjustment unit 130 acquires, for example, the following data from the EV electric power amount prediction unit 120, as a prediction result of a residual battery capacity (a residual capacity at return when the EV returns from business) of “◯ month ◯ day 15:00 to 24:00” and a prediction error (expressed by ±) thereof.
EV1: Battery residual capacity: 50%±30%
EV2: Battery residual capacity: 20%±5%
EV3: Battery residual capacity: 50%±10%
   The dischargeable electric power amount and the chargeable electric power amount for each EV can be calculated from the residual battery capacity. In the subsequent processing, it is assumed that the processing is performed at a certain future time. This time is referred to as a “target time”.

### <S103>

In S103, the charge/discharge surplus power adjustment unit 130 determines whether the discharge from the EV is necessary at the target time, based on the data acquired in S101. If the determination result of S103 is Yes (discharge is necessary), the process proceeds to S104, and if the determination result is No (charging is necessary in the case of No), the process proceeds to S109.

### <S104 to S108>

In S104 to which the process proceeds when the discharge from the EV is necessary, the charge/discharge surplus power adjustment unit 130 allocates an EV having a small prediction error among the plurality of EVs for discharge.

The EV having the small prediction error is, for example, an EV in which the magnitude of the prediction error is equal to or less than a predetermined threshold. Further, the EV having the small prediction error may be the EV up to the Nth higher order when the EVs are arranged in order from the one having a smaller prediction error. N may be a predetermined number (1, 2, 3, or the like), or may be a number of X % (e.g., 30% or the like) of the number of all EVs.

Here, it is assumed that only the EV having the small prediction error cannot cover the required discharge amount. If only the EV having the small prediction error can cover the required discharge amount, S105 to be described below need not be performed. In other words, it is not necessary to use the EV having a large prediction error for the discharge.

In S105, the charge/discharge surplus power adjustment unit 130 determines that, for an EV having a large prediction error, by assuming that the residual battery capacity is a minimum value (referred to as an adjustment prediction value) in a range of a prediction value obtained based on the prediction error, the EV is assigned to discharge.

The EV having the large prediction error may be an EV obtained by excluding “the EV having the small prediction error” from all the EVs, or may be an EV having a magnitude of the prediction error equal to or greater than a predetermined threshold. The threshold in S104 may be the same as or different from the threshold in S105.

In S106, it is determined whether the residual battery capacity can be covered by using the residual battery capacities of the EVs allocated in S104 and S105 for discharge.

Regarding the residual battery capacity used for the determination, a prediction value itself is used for the EV (with the small prediction error) allocated in S104, and an adjustment prediction value that is a minimum value in a range of the prediction value is used for the EV (with the large prediction error) allocated in S105.

For example, it is assumed that EV2 (residual battery capacity: 20%±5%) is assigned to the discharge in S104, and EV1 (residual battery capacity: 50%±30%) is assigned to the discharge in S105.

The charge/discharge surplus power adjustment unit 130 uses a prediction value 20% of the battery residual capacity for EV2 when calculating (estimating) the electric power amount usable for discharge, and uses 20% of the minimum value in 20% to 80%, which is the range of the prediction value in which the error is taken account as the adjustment prediction value for EV1.

Assuming that the discharge electric power amount corresponding to 20% of the battery residual capacity of EV2 is P2, and the discharge electric power amount corresponding to 20% of the battery residual capacity of EV1 is P1, and the required discharge amount is PX, in S106, the charge/discharge surplus power adjustment unit 130 determines whether “P2+P1>PX” is true, thereby determining whether the required discharge amount can be covered by only these EVs.

If the determination in S106 is Yes (OK only by the EVs), the process proceeds to S108. If the determination in S106 is No (NG only by the EVs), the process proceeds to S107.

In S107, the charge/discharge surplus power adjustment unit 130 allocates the storage battery 500 for discharge for an insufficient electric power amount (in the above example, “PX−(P2+P1)”) among the required discharge amounts. After S107, the process proceeds to S108.

In S108, the charge/discharge surplus power adjustment unit 130 records a result allocated at the target time in a storage unit, such as a memory. For example, when EV1 and EV2 are allocated for discharge at the target time, information corresponding to “the target time, discharge, EV1, and EV2” are recorded in the storage unit.

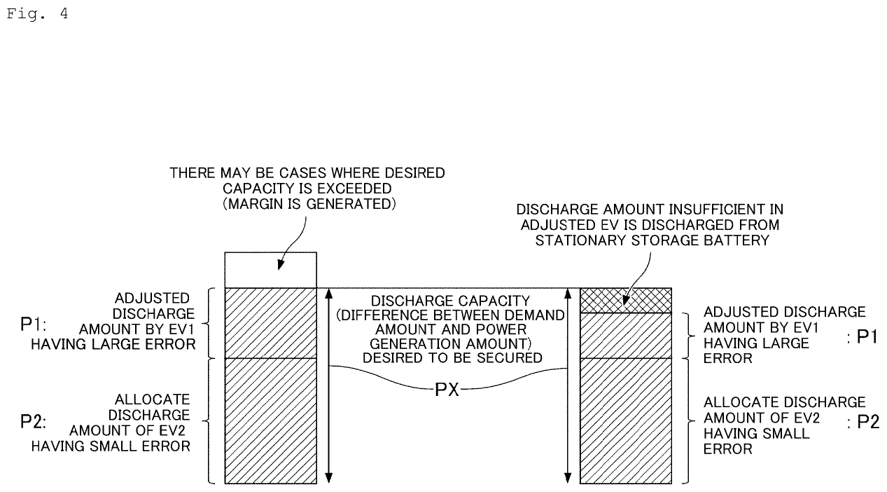

The images of S106 and S107 when P2, P1, and PX are used are illustrated in FIG. 4.

In the above example, for an EV having a large prediction error, the minimum value in the range of the prediction value obtained based on the prediction error is used as the adjustment prediction value in the calculation of the dischargeable amount, but this is an example.

For the EV having the large prediction error, a value other than the minimum value may be used as the adjustment prediction value, if the value is less than the prediction value itself in the range of the prediction value obtained based on the prediction error in the calculation of the discharge amount.

For example, in an example of using EV1 (of the battery residual capacity: 50%±30%), 30%, which is less than the prediction value 50% but greater than the minimum value of the prediction value range from 20% to 80%, may be used as the adjustment prediction value.

### <S109 to S112, S108>

In S109 performed when charging to the EV is required, the charge/discharge surplus power adjustment unit 130 allocates an EV having a small prediction error among the plurality of EVs for charging. The “EV with the small prediction error” has been described above.

Here, it is assumed that the EV having the small prediction error cannot cover the required charging amount alone. If the EV having the small prediction error can cover the required charging amount alone, S110 to be described below need not be performed.

In S110, the charge/discharge surplus power adjustment unit 130 determines that, for an EV having a large prediction error, by assuming that the battery residual capacity is a maximum value (referred to as an adjustment prediction value) in a range of a prediction value obtained based on the prediction error, the EV is assigned for charging. The “EV having the large prediction error” has been described above.

In S111, the charge/discharge surplus power adjustment unit 130 determines whether the required charge amount can be covered by using the batteries of the EVs allocated in S109 and S110 for charging.

For the battery residual capacity used for the determination, a prediction value itself is used for the EV (with the small prediction error) allocated in S109, and a maximum value of the prediction value is used as the adjustment prediction value for the EV (with the large prediction error) allocated in S110.

For example, it is assumed that EV2 (battery residual capacity: 20%±5%) is assigned for charging in S109, and EV1 (battery residual capacity: 50%±30%) is assigned for charging in S110.

The charge/discharge surplus power adjustment unit 130 uses a prediction value 20% of the battery residual capacity for EV2 when calculating (estimating) the electric power amount usable for charging, and uses the value 80% that is the maximum value in 20% to 80%, which is the range of the prediction value in which the error is taken account as the adjustment prediction value for EV1.

Assuming that a charge electric power amount corresponding to 20% of the battery residual capacity of EV2 (electric power amount that can be charged until the battery is fully charged) is P2, a charge electric power amount corresponding to 80% of the battery residual capacity of EV1 is P1, and a charge necessary amount is PX, by determining whether “P2+P1≥PX” is satisfied, the charge/discharge surplus power adjustment unit 130 determines whether the required charge amount can be covered only by the EVs in S111.

If the determination in S111 is Yes (OK only by the EVs), the process proceeds to S108. If the determination in S111 is No (NG only by the EVs), the process proceeds to S112.

In S112, the charge/discharge surplus power adjustment unit 130 allocates the storage battery 500 as a charge (for storage) for an insufficient electric power amount (in the above example, “PX−(P2+P1)”) among the required charge amounts. After S112, the process proceeds to S108.

In S108, the charge/discharge surplus power adjustment unit 130 records a result allocated at the target time in a storage unit, such as a memory. For example, when EV1 and EV2 are allocated for charging at the target time, information corresponding to “the target time, charging, EV1, and EV2” are recorded in the storage unit.

In the above example, for the EV having the large prediction error, although the maximum value in the range of the prediction value obtained based on the prediction error is used as the adjustment prediction value in estimation of the chargeable amount, this is an example.

For the EV having the large prediction error, a value other than the maximum value may be used as the adjustment prediction value if the value is greater than the prediction value itself in the range of the prediction value obtained based on the prediction error in estimation of the chargeable amount.

For example, in an example of using EV1 (battery residual capacity: 50%±30%), 70%, which is greater than the prediction value 50% but less than the maximum value among 20% to 80% of the prediction value range, may be used as the adjustment prediction value.

### Example of Configuration and Operation of Required Electric Power Amount Prediction Unit 110

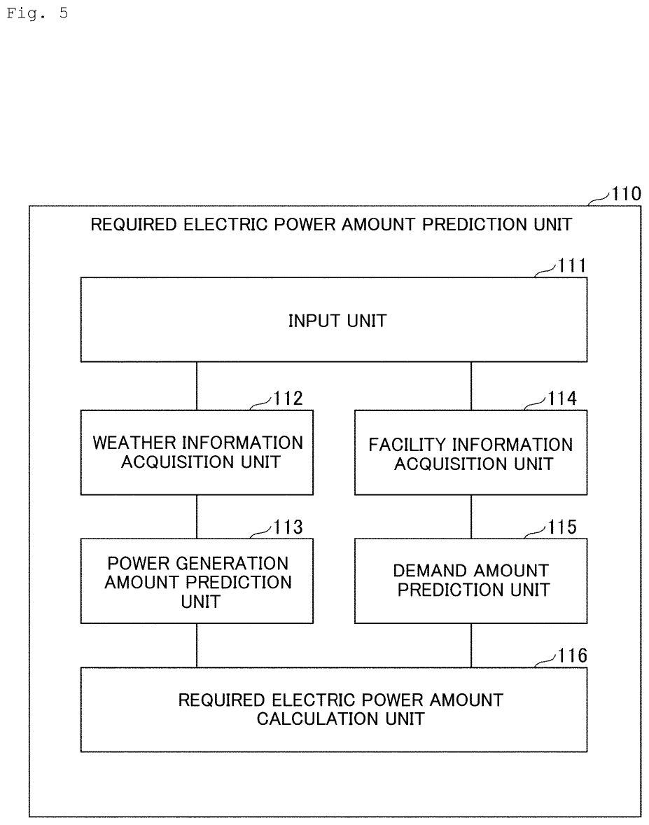

The required electric power amount prediction unit 110 may have any configuration as long as the required discharge amount/required charge amount described in S101 can be calculated. FIG. 5 illustrates a configuration example of the required electric power amount prediction unit 110.

As illustrated in FIG. 5, the required electric power amount prediction unit 110 includes an input unit 111, a weather information acquisition unit 112, a power generation amount prediction unit 113, a facility information acquisition unit 114, a demand amount prediction unit 115, and a required electric power amount calculation unit 116.

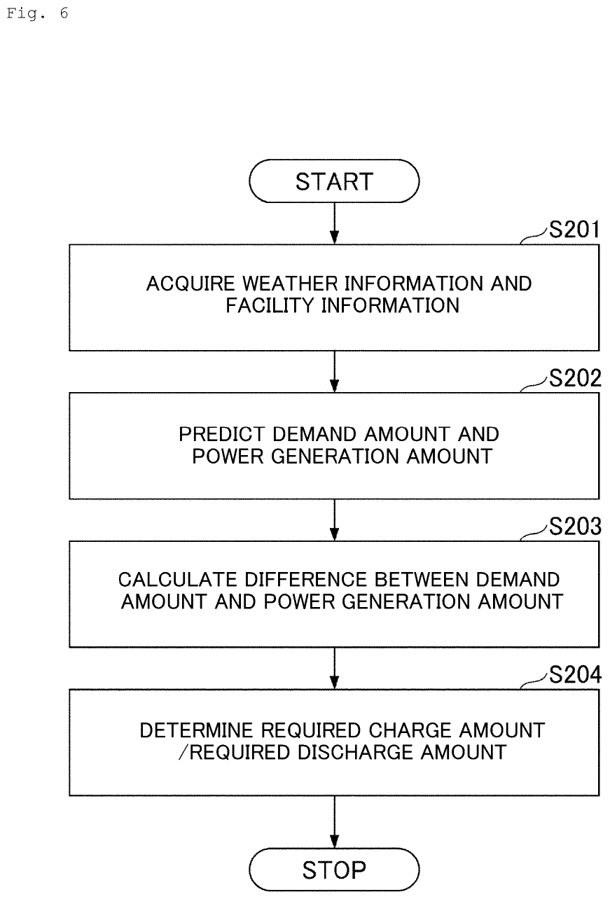

Next, an operation example of the required electric power amount prediction unit 110 having the above configuration example will be described referring to a flowchart of FIG. 6.

In S201, the weather information acquisition unit 112 and the facility information acquisition unit 114 acquire weather information and facility information via the input unit 111. The weather information is information of weather affecting the demand amount of the building and the power generation amount of the PV power generation. The facility information is information on a device that becomes the load in a building, information on a PV power generation device, and the like.

In S202, the demand amount prediction unit 115 predicts a demand amount in the building based on the information acquired in S201. The power generation amount prediction unit 113 predicts the power generation amount based on the information acquired in S201.

In S203, the required electric power amount calculation unit 116 calculates a difference between the demand amount and the power generation amount for each future time, based on the prediction result in S202.

In S204, the required electric power amount calculation unit 116 determines a required charge amount/a required discharge amount for each future time, based on the difference in S203.

### Example of Configuration and Operation of EV Electric Power Amount Prediction Unit 120

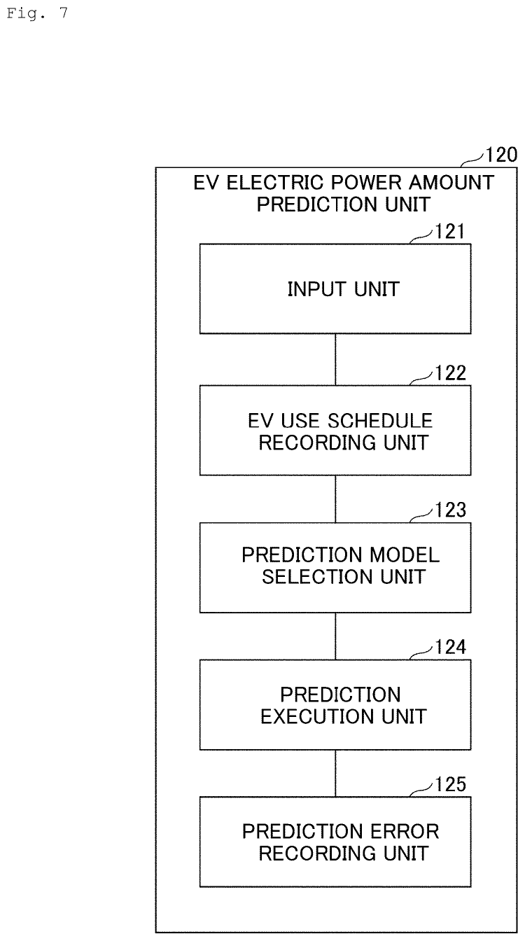

The EV electric power amount prediction unit 120 may have any configuration as long as it can calculate the prediction value of the battery residual capacity (SOC) for each EV and the prediction error for the prediction value described in S102. FIG. 7 illustrates a configuration example of the EV electric power amount prediction unit 120.

As illustrated in FIG. 7, the EV electric power amount prediction unit 120 includes an input unit 121, an EV use schedule recording unit 122, a prediction model selection unit 123, a prediction execution unit 124, and a prediction error recording unit 125.

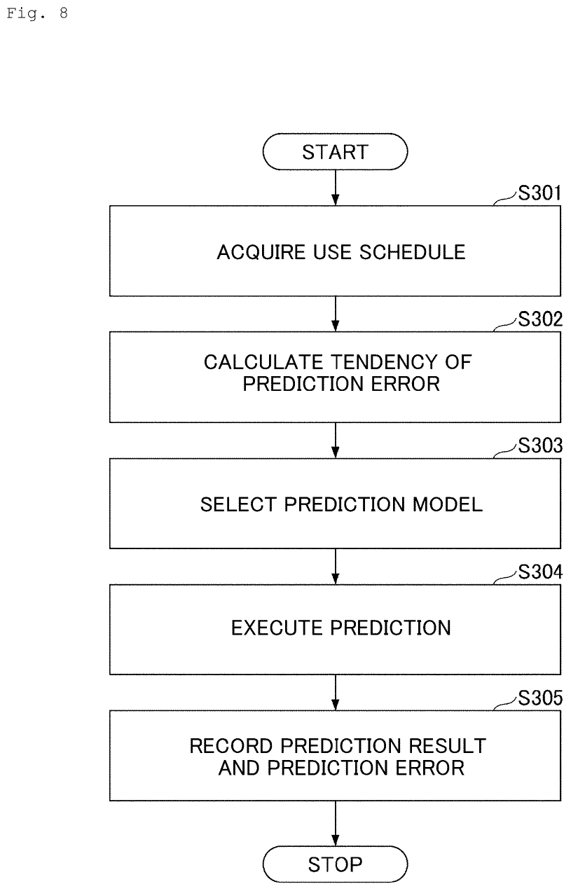

Next, an operation example of the EV electric power amount prediction unit 120 will be described referring to a flowchart of FIG. 8. As the premise of the processing of FIG. 8, it is assumed that a prediction model (a plurality of prediction models) has already been constructed from the history data (the user, the day and time of departure/return, the travel distance, the average speed, the travel route (the start point, the destination), the power consumption, and the like), and the prediction model is stored in the storage unit, such as a memory. The construction of the prediction model and the prediction itself using the prediction model are the existing techniques. The following processing flow is applied to each EV. Hereinafter, an EV for the application is referred to as a target EV.

In S301, a use schedule of the target EV is input from the input unit 301, and recorded (stored) in the EV use schedule recording unit 122. The use schedule for the target EV is information, for example, such as “user: A, use schedule date and time: ∘ month ∘ day 10:00 departure to 14:00 return, departure place: X, destination: Y.”

In S302, the prediction model selection unit 123 reads the use schedule of the target EV from the EV use schedule recording unit 122, and calculates a tendency of a prediction error based on the use schedule. Specifically, because the prediction error increases in the prediction model as the average speed of the EV decreases, the prediction model selection unit 123 calculates the average speed of the target EV from the use schedule.

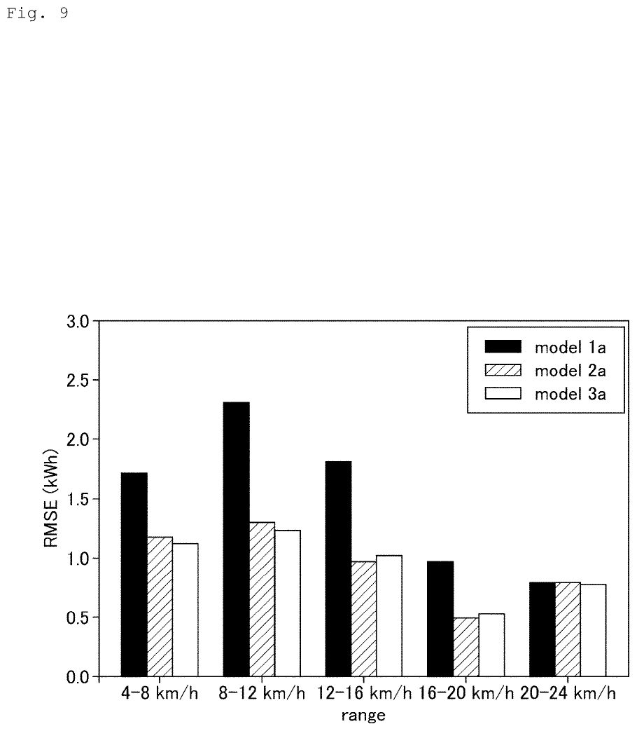

FIG. 9 is a diagram illustrating an example of the relationship between the speed and the errors (RMSE) of three kinds of prediction models. As illustrated in FIG. 9, as the average EV speed decreases, the prediction error in the prediction model increases. Also, it is understood that there is a difference in the error depending on the model even at the same speed.

In S303 of FIG. 8, the prediction model selection unit 123 selects a prediction model based on the average speed, which is a factor for determining the magnitude of the prediction error. As described above, since there is a difference in the error depending on the average speed between the plurality of prediction models, the prediction model selection unit 123 selects the prediction model with the highest accuracy (the smallest error) for the average speed of the target EV.

In the present embodiment, the prediction error is determined by the average speed and depending on which prediction model is selected. However, the prediction error may be determined (calculated) by a method other than this method.

In S304, the prediction execution unit 124 predicts the battery residual capacity at the time of return for the target EV based on the input use schedule, using the prediction model selected in S303. The power consumption from the start to the return may be predicted to subtract the power consumption from 100% and obtain the battery residual capacity.

In S305, the prediction execution unit 124 records a prediction result and a prediction error (e.g., the battery residual capacity: 50%±30%) in the prediction error recording unit 125.

### Other Examples

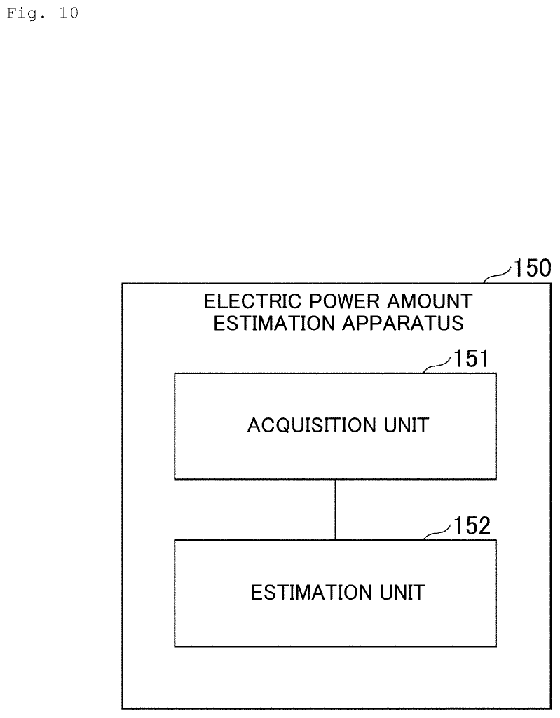

As a device to which the technique according to the present invention is applied, an electric power amount estimation apparatus 150 as illustrated in FIG. 10 can be used. The charge/discharge surplus power calculation device 100 is an example of the electric power amount estimation apparatus 150. As illustrated in FIG. 10, the electric power amount estimation apparatus 150 includes an acquisition unit 151 and an estimation unit 152.

The electric power amount estimation apparatus 150 estimates a dischargeable amount that can be discharged from one or more batteries. The acquisition unit 151 acquires a residual capacity prediction value and a prediction error of each of one or more batteries. The estimation unit 152 determines an adjustment prediction value that is a value less than the residual capacity prediction value based on the prediction error for at least one battery of the one or more batteries, and estimates the dischargeable amount by using the adjustment prediction value.

The electric power amount estimation apparatus 150 can also estimate a chargeable amount capable of charging one or more batteries. In this case, the acquisition unit 151 acquires a residual capacity prediction value and a prediction error of each of the one or more batteries. The estimation unit 152 determines an adjustment prediction value that is a value greater than the residual capacity prediction value, based on the prediction error for at least one battery of the one or more batteries, and estimates the chargeable amount by using the adjustment prediction value.

The estimation unit 152 uses, for example, the adjustment prediction value for a battery having a prediction error greater than a threshold.

### Hardware Configuration Example

Any of the devices described in the present embodiment (the charge/discharge surplus power calculation device 100 and the electric power amount estimation apparatus 150) can be realized by, for example, causing a computer to execute a program. This computer may be a physical computer or may be a virtual machine on the cloud.

That is, the devices can be realized by executing programs corresponding to processing performed by the devices using hardware resources, such as a CPU and a memory contained in a computer. The above programs can be recorded on a computer-readable recording medium (such as a portable memory) and can be stored or distributed. Further, the above program can also be provided through a network such as the Internet or e-mail.

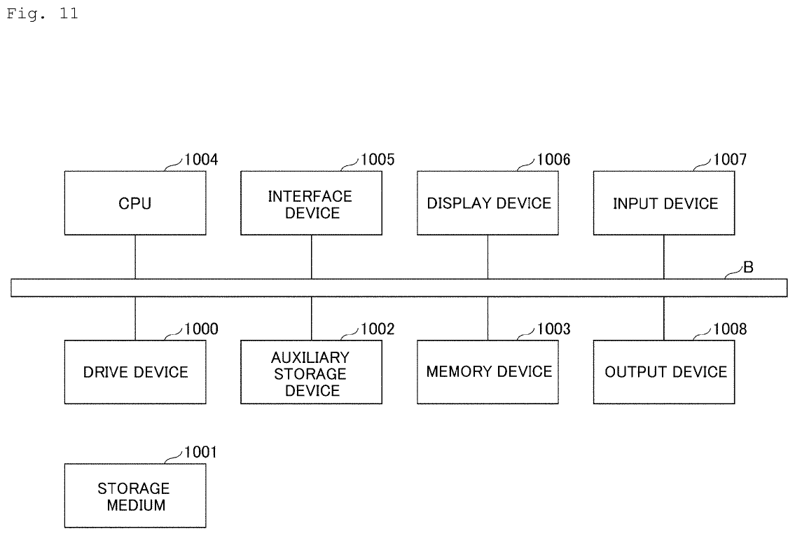

FIG. 11 is a diagram illustrating a hardware configuration example of the computer. The computer illustrated in FIG. 11 includes a drive device 1000, an auxiliary storage device 1002, a memory device 1003, a CPU 1004, an interface device 1005, a display device 1006, an input device 1007, an output device 1008, and the like, which are connected to each other by a bus BS. The computer may further include a GPU.

A program for realizing processing in the computer is provided by, for example, a recording medium 1001, such as a CD-ROM or a memory card. When the recording medium 1001 having the program stored therein is set in the drive device 1000, the program is installed in the auxiliary storage device 1002 from the recording medium 1001 via the drive device 1000. However, the program does not necessarily have to be installed from the recording medium 1001, and may be downloaded from another computer via a network. The auxiliary storage device 1002 stores the installed program and also stores necessary files, data, and the like.

The memory device 1003 reads and stores the program from the auxiliary storage device 1002 when there is an instruction to start the program. The CPU 1004 realizes functions related to the apparatus according to the program stored in the memory device 1003. The interface device 1005 is used as an interface for connection to a network. The display device 1006 displays a graphical user interface (GUI) or the like according to a program. The input device 1007 is configured of a keyboard, a mouse, buttons, a touch panel, or the like, and is used to input various operation instructions. The output device 1008 outputs a calculation result.

### Summary, Effects, and the Like of Embodiments

As described above, the technique described in the present embodiment makes it possible to appropriately estimate the dischargeable amount or the chargeable amount of the battery.

Further, in a more specific embodiment, since the EV including an unallowable error can be determined from the use schedule information, and the electric power amount on the safety side capable of being surely charged and discharged can be estimated (adjusted), thus, it is possible to create a highly reliable charge/discharge plan. In particular, in order to prevent the power failure in a situation where the demand is tight, it is required to ensure the remaining capacity of discharge, but this can be realized by the technique according to the present embodiment.

Regarding the above embodiment, the following Appendices are further disclosed.

### APPENDIX

### (Appendix 1)

An electric power amount estimation apparatus that estimates a dischargeable amount that is dischargeable from one or more batteries, the electric power amount estimation apparatus including:
a memory; and
at least one processor connected to the memory, where the processor
acquires a residual capacity prediction value and a prediction error of each of the one or more batteries; and
determines an adjustment prediction value that is a value less than the residual capacity prediction value, for at least one battery among the one or more batteries, based on the prediction error, and estimates the dischargeable amount, using the adjustment prediction value.

### (Appendix 2)

The electric power amount estimation apparatus set forth in Appendix 1,
in which the processor estimates the dischargeable amount for a battery having the prediction error greater than a threshold, using the adjustment prediction value.

### (Appendix 3)

The electric power amount estimation apparatus set forth in Appendix 1 or 2,
in which the processor estimates the dischargeable amount for a battery having the prediction error less than a threshold, using the residual capacity prediction value.

### (Appendix 4)

An electric power amount estimation apparatus that estimates a chargeable amount that is chargeable to one or more batteries, the electric power amount estimation apparatus including:
a memory; and
at least one processor connected to the memory, wherein the processor
acquires a residual capacity prediction value and a prediction error of each of the one or more batteries; and
determines an adjustment prediction value that is a value greater than the residual capacity prediction value, for at least one battery among the one or more batteries, based on the prediction error, and estimates the chargeable amount, using the adjustment prediction value.

### (Appendix 5)

The electric power amount estimation apparatus set forth in Appendix 4,
in which the processor estimates the chargeable amount on a battery having the prediction error greater than a threshold, using the adjustment prediction value.

### (Appendix 6)

An electric power amount estimation method performed by an electric power amount estimation apparatus that estimates a dischargeable amount that is dischargeable from one or more batteries, the electric power amount estimation method including:
an acquisition step of acquiring a residual capacity prediction value and a prediction error of each of the one or more batteries; and
an estimation step of determining an adjustment prediction value that is a value less than the residual capacity prediction value, for at least one battery among the one or more batteries, based on the prediction error, and estimating the dischargeable amount, using the adjustment prediction value.

### (Appendix 7)

An electric power amount estimation method performed by an electric power amount estimation apparatus that estimates a chargeable amount that is chargeable to one or more batteries, the electric power amount estimation method including:
an acquisition step of acquiring a residual capacity prediction value and a prediction error of each of the one or more batteries; and
an estimation step of determining an adjustment prediction value that is a value greater than the residual capacity prediction value, for at least one battery among the one or more batteries, based on the prediction error, and estimating the chargeable amount, using the adjustment prediction value.

### (Appendix 8)

A non-transitory storage medium that stores a program for causing a computer to function as each unit of the electric power amount estimation apparatus according to any one of Appendices 1 to 5.

Although the present embodiment has been described above, the present invention is not limited to such a specific embodiment, and various modifications and changes can be made within the scope of the gist of the present invention described in the claims.

Reference Signs List

| | |
|---|---|
| 100 | Charge/discharge surplus power calculation |
| | device |
| 110 | Required electric power amount prediction unit |
| 111 | Input unit |
| 112 | Weather information acquisition unit |
| 113 | Power generation amount prediction unit |
| 114 | Facility information acquisition unit |
| 115 | Demand amount prediction unit |
| 116 | Required electric power amount calculation unit |
| 120 | EV electric power amount prediction unit |
| 121 | Input unit |
| 122 | EV use schedule recording unit |
| 123 | Prediction model selection unit |
| 124 | Prediction execution unit |
| 125 | Prediction error recording unit |
| 130 | Charge/discharge surplus power adjustment unit |
| 140 | Output part |
| 150 | Electric power amount estimation apparatus |
| 151 | Acquisition unit |
| 152 | Estimation unit |
| 200 | Network |
| 300 | PV power generation device |
| 400 | Load |
| 500 | Storage battery |
| 1000 | Drive device |
| 1001 | Recording medium |
| 1002 | Auxiliary storage device |
| 1003 | Memory device |
| 1004 | CPU |
| 1005 | Interface device |
| 1006 | Display device |
| 1007 | Input device |
| 1008 | Output device |

1. An electric power amount estimation apparatus comprising:
a processor; and
a memory storing program instructions that cause the processor to:
acquire a residual capacity prediction value and a prediction error of each of one or more batteries; and
determine an adjustment prediction value that is a value less than the residual capacity prediction value, for at least one battery among the one or more batteries, based on the prediction error, and estimate a dischargeable amount that is dischargeable from the one or more batteries, using the adjustment prediction value.

2. The electric power amount estimation apparatus according to claim 1, wherein the program instructions cause the processor to estimate the dischargeable amount for a battery having a prediction error greater than a threshold, using the adjustment prediction value.

3. The electric power amount estimation apparatus according to claim 1, wherein the program instructions cause the processor to estimate the dischargeable amount for a battery having a prediction error less than a threshold, using the residual capacity prediction value.

4. An electric power amount estimation apparatus comprising:
a processor; and
a memory storing program instructions that cause the processor to:
acquire a residual capacity prediction value and a prediction error of each of one or more batteries; and
determine an adjustment prediction value that is a value greater than the residual capacity prediction value, for at least one battery among the one or more batteries, based on the prediction error, and estimate a chargeable amount that is chargeable to one or more batteries, using the adjustment prediction value.

5. The electric power amount estimation apparatus according to claim 4, wherein the program instructions cause the processor to estimate the chargeable amount for a battery having a prediction error greater than a threshold, using the adjustment prediction value.

6. An electric power amount estimation method performed by an electric power amount estimation apparatus that estimates a dischargeable amount that is dischargeable from one or more batteries, the electric power amount estimation method comprising:
acquiring a residual capacity prediction value and a prediction error of each of the one or more batteries; and
determining an adjustment prediction value that is a value less than the residual capacity prediction value, for at least one battery among the one or more batteries, based on the prediction error, and estimating the dischargeable amount, using the adjustment prediction value.

7. (canceled)

8. A non-transitory computer-readable recording medium having stored therein a program for causing a computer to perform the electric power amount estimation method according to claim 6.
